(19) United States
(12) Patent Application Publication
(10) Pub. No.: US 2006/0213868 A1
(43) Pub. Date: Sep. 28, 2006

(54) Low-dishing composition and method for chemical-mechanical planarization with branched-alkylphenol-substituted benzotriazole

(76) Inventors: Junaid Ahmed Siddiqui, Richmond, VA (US); Timothy Frederick Compton, Casa Grande, AZ (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 11/374,714

(22) Filed: Mar. 14, 2006

Related U.S. Application Data
(60) Provisional application No. 60/664,338, filed on Mar. 23, 2005.

(51) Int. Cl. C09K 13/00; C03C 15/00; H01L 21/302

(52) U.S. Cl. 216/88; 252/79.1; 216/89; 438/692

(57) ABSTRACT

A composition and associated method for chemical mechanical planarization (or other polishing) are described. The composition comprises a branched-alkylphenol-substituted-benzotriazole. The composition affords low dishing, high metal removal rates, and high selectivities for removal of copper in relation to barrier layer materials and dielectric materials whilst minimizing local erosion effects in CMP. The composition may further comprise an oxidizing agent in which case the composition is particularly useful in conjunction with the associated method for metal CMP applications (e.g., copper CMP). The composition may also further comprise an isothiazoline compound to synergistically impart lower dishing levels during CMP processing.

### CROSS REFERENCE TO RELATED APPLICATION

This application claims the benefit of U.S. Provisional Patent Application No. 60/664,338 filed Mar. 23, 2006.

### BACKGROUND OF THE INVENTION

This invention relates generally to the chemical-mechanical polishing (CMP) of metal substrates on semiconductor wafers and slurry compositions therefor. In particular, the present invention relates to a CMP slurry composition which is characterized to afford low dishing, high copper removal rates and high selectivities for removal of copper in relation to barrier layer materials and dielectric materials whilst minimizing local erosion effects during CMP processing of substrates comprised of metal, barrier layer material, and dielectric material. This invention is especially useful for copper CMP and most especially for copper CMP step 1.

Chemical mechanical planarization (chemical mechanical polishing, CMP) for planarization of semiconductor substrates is now widely known to those skilled in the art and has been described in numerous patents and open literature publications. Some introductory references on CMP are as follows: “Polishing Surfaces for Integrated Circuits”, by B. L. Mueller and J. S. Steckenrider, Chemtech, February, 1998, pages 38-46; H. Landis et al., Thin Solids Films, 220 (1992), page 1; and “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a dielectric layer. Multilevel circuit traces, typically formed from aluminum or an aluminum alloy or copper, are patterned onto the dielectric layer substrate.

CMP processing is often employed to remove and planarize excess metal at different stages of semiconductor manufacturing. Various metals and metal alloys have been used at different stages of semiconductor manufacturing, including tungsten, aluminum, copper, tantalum, tantalum nitride, titanium, titanium nitride, ruthenium, platinum, iridium, and combinations thereof. For example, one way to fabricate a multilevel copper interconnect or planar copper circuit traces on a dielectric substrate is referred to as the damascene process. In a semiconductor manufacturing process typically used to form a multilevel copper interconnect, metallized copper lines or copper vias are formed by electrochemical metal deposition followed by copper CMP processing. In a typical process, the interlevel dielectric (ILD) surface is patterned by a conventional dry etch process to form vias and trenches for vertical and horizontal interconnects and make connection to the sublayer interconnect structures. The patterned ILD surface is coated with an adhesion-promoting layer such as titanium or tantalum and/or a diffusion barrier layer such as titanium nitride or tantalum nitride over the ILD surface and into the etched trenches and vias. The adhesion-promoting layer and/or the diffusion barrier layer is then overcoated with copper, for example, by a seed copper layer and followed by an electrochemically deposited copper layer. Electro-deposition is continued until the structures are filled with the deposited metal. Finally, CMP processing is used to remove the copper overlayer, adhesion-promoting layer, and/or diffusion barrier layer, until a planarized surface with exposed elevated portions of the dielectric (silicon dioxide and/or low-k) surface is obtained. The vias and trenches remain filled with electrically conductive copper forming the circuit interconnects. The adhesion-promoting layer plus diffusion barrier layer is typically collectively referred to as the “barrier layer.”

When one-step copper CMP processing is desired, it is usually important that the removal rate of the metal and barrier layer material be significantly higher than the removal rate for dielectric material in order to avoid or minimize dishing of metal features or erosion of the dielectric. Alternatively, a multi-step copper CMP process may be employed involving the initial removal and planarization of the copper overburden, referred to as a step 1 copper CMP process, followed by a barrier layer CMP process. The barrier layer CMP process is frequently referred to as a barrier or step 2 copper CMP process. Previously, it was believed that the removal rate of the copper and the barrier layer materials must both greatly exceed the removal rate of dielectric so that polishing effectively stops when elevated portions of the dielectric are exposed. The ratio of the removal rate of copper to the removal rate of dielectric base is called the “selectivity” for removal of copper in relation to dielectric during CMP processing of substrates comprised of copper, barrier layer materials, and dielectric materials. The ratio of the removal rate of copper to the removal rate of barrier layer materials is called the “selectivity” for removal of copper in relation to barrier layer materials during CMP processing of substrates comprised of copper, barrier layer materials, and dielectric materials. Barrier layer materials include tantalum, tantalum nitride, tungsten, noble metals such as ruthenium and ruthenium oxide, and combinations thereof. When CMP slurries with high selectivity for removal of copper and barrier layer materials in relation to dielectric are used, the copper layers are easily over-polished creating a depression or “dishing” effect in the copper vias and trenches. This feature distortion is unacceptable due to lithographic and other constraints in semiconductor manufacturing.

Another feature distortion that is unsuitable for semiconductor manufacturing is called “erosion.” Erosion is the topography difference between a field of dielectric and a dense array of copper vias or trenches. In CMP, the materials in the dense array maybe removed or eroded at a faster rate than the surrounding field of dielectric. This causes a topography difference between the field of dielectric and the dense copper array.

A typically used CMP slurry has two actions, a chemical component and a mechanical component. An important consideration in slurry selection is “passive etch rate.” The passive etch rate is the rate at which copper is dissolved by the chemical component alone and should be significantly lower than the removal rate when both the chemical component and the mechanical component are involved. A large passive etch rate leads to dishing of the copper trenches and copper vias, and thus, preferably, the passive etch rate is less than 10 nanometers per minute.

A number of systems for CMP of copper have been disclosed. A few illustrative examples are listed next. Kumar et al. in an article entitled “Chemical-Mechanical Polishing of Copper in Glycerol Based Slurries” (Materials Research Society Symposium Proceedings, 1996) disclose a slurry that contains glycerol and abrasive alumina particles. An article by Gutmann et al. entitled “Chemical-Mechanical Polishing of Copper with Oxide and Polymer Interlevel Dielectrics” (Thin Solid Films, 1995) discloses slurries based on either ammonium hydroxide or nitric acid that may contain benzotriazole (BTA) as an inhibitor of copper dissolution. Luo et al. in an article entitled “Stabilization of Alumina Slurry for Chemical-Mechanical Polishing of Copper” (Langmuir, 1996) discloses alumina-ferric nitrate slurries that contain polymeric surfactants and BTA. Carpio et al. in an article entitled “Initial Study on Copper CMP Slurry Chemistries” (Thin Solid Films, 1995) disclose slurries that contain either alumina or silicon particles, nitric acid or ammonium hydroxide, with hydrogen peroxide or potassium permanganate as an oxidizer.

In relation to copper CMP, the current state of this technology involves use of a two-step process to achieve local and global planarization in the production of IC chips. During step 1 of a copper CMP process, the overburden copper is removed. Then step 2 of the copper CMP process follows to remove the barrier layer materials and achieve both local and global planarization. Generally, after removal of overburden copper in step 1, polished wafer surfaces have non-uniform local and global planarity due to differences in the step heights at various locations of the wafer surfaces. Low density features tend to have higher copper step heights whereas high density features tend to have low step heights. Due to differences in the step heights after step 1, selective slurries are highly desirable for step 2 copper CMP for the selective removal of barrier layer materials in relation to copper and for the selective removal of dielectric materials in relation to copper. The ratio of the removal rate of barrier layer materials to the removal rate of copper is called the “selectivity” for removal of barrier layer materials in relation to copper during CMP processing of substrates comprised of copper, barrier layer materials and dielectric materials.

There are a number of theories as to the mechanism for chemical-mechanical polishing of copper. An article by Zeidler et al. (Microelectronic Engineering, 1997) proposes that the chemical component forms a passivation layer on the copper changing the copper to a copper oxide. The copper oxide has different mechanical properties, such as density and hardness, than metallic copper and passivation changes the polishing rate of the abrasive portion. The above article by Gutmann et al. discloses that the mechanical component abrades elevated portions of copper and the chemical component then dissolves the abraded material. The chemical component also passivates recessed copper areas minimizing dissolution of those portions.

These are two general types of layers that can be polished. The first layer is interlayer dielectrics (ILD), such as silicon oxide, silicon nitride, and low-k films including carbon-doped oxides. The second layer is metal layers such as tungsten, copper, aluminum, etc., which are used to connect the active devices.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal and enhancing the diffusion of reactants and products to and away from the surface by mixing and by reducing the thickness of the boundary layer.

While prior art CMP systems are capable of removing a copper overlayer from a interlayer dielectric substrate, the systems do not satisfy the rigorous demands of the semiconductor industry. These requirements can be summarized as follows. First, there is a need for high removal rates of copper to satisfy throughput demands. Secondly, there must be excellent topography uniformity across the substrate. Finally, the CMP method must minimize local dishing and erosion effects to satisfy ever increasing lithographic demands.

### BRIEF SUMMARY OF THE INVENTION

In one embodiment, the invention is a polishing composition comprising:

a) an abrasive; and

b) a compound having the structure: 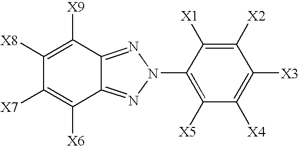
wherein at least one of X₁—X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group.

The polishing composition is useful in chemical-mechanical polishing (CMP), especially in metal CMP.

In another embodiment, the invention is a chemical mechanical planarization method for planarizing a substrate comprising copper, dielectric, and barrier layer, said method comprising the steps of:

A) placing a substrate in contact with a polishing pad;

B) delivering a polishing composition comprising
a) an abrasive; and
b) a compound having the structure: 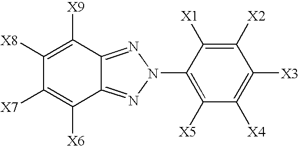
   wherein at least one of X₁—X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group; and

C) polishing the substrate with the polishing composition.

In yet another embodiment, the invention is a method of polishing comprising the steps of:

A) placing a substrate in contact with a polishing pad;

B) delivering a polishing composition comprising
a) an abrasive; and
b) a compound having the structure: 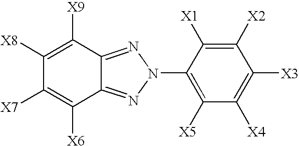
   wherein at least one of X₁—X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group; and

C) polishing the substrate with the polishing composition.

### DETAILED DESCRIPTION OF THE INVENTION

It has been found that CMP polishing compositions comprising a triazole compound having the structure given supra and an abrasive afford low dishing, high removal rates of metal (e.g., copper), and high selectivities for removal of copper in relation to barrier layer materials and dielectric materials whilst minimizing erosion effects during CMP processing. Consequently these polishing compositions are particularly useful in copper CMP processing (e.g., step 1 copper CMP).

Suitable triazole compounds for this invention include, but are not limited to, compounds having the structures: 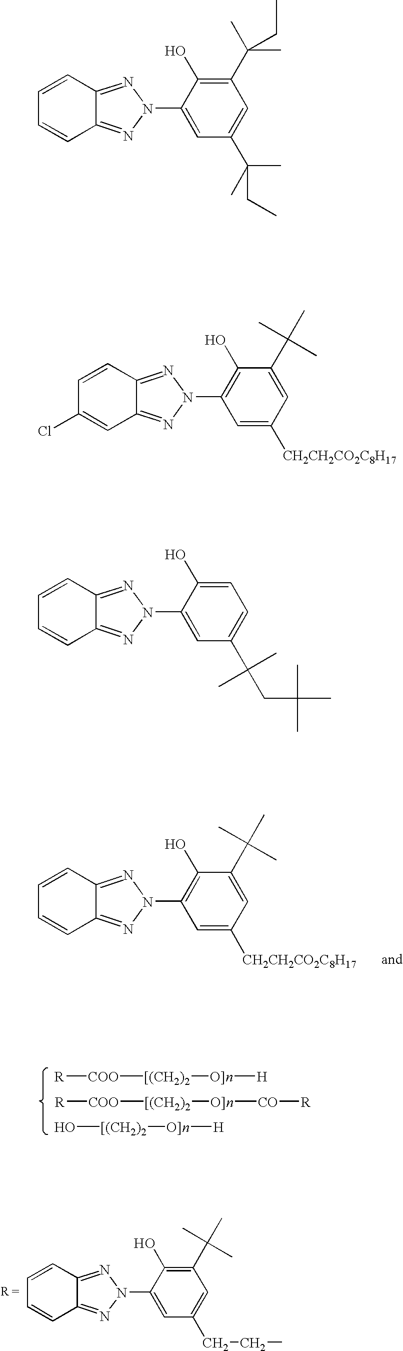
and combinations thereof. The triazole compound having the structure given supra for this invention is present in the slurry in a concentration of about 0.001 weight % to about 0.1 weight % of the total weight of the slurry. In one embodiment, the triazole compound having the structure given supra for this invention is present in a concentration of about 0.002 weight % to about 0.05 weight % of the total weight of the slurry. In a further embodiment, the triazole compound having the structure given supra for this invention is present in a concentration of about 0.005 weight % to about 0.03 weight % of the total weight of the slurry. Suitable triazole compounds for this invention include, but are not limited to, TINUVIN 328, TINUVIN 234, TINUVIN, 326, TINUVIN 109, TINUVIN 384-2, TINUVIN 329, TINUVIN 213, TINUVIN 99-2 and combinations thereof.

Both standard (unmodified) abrasives and organometallic-modified abrasives can be employed in this invention. Suitable unmodified abrasives include, but are not limited to, silica, alumina, titania, zirconia, germania, ceria, and co-formed products thereof, and mixtures thereof. An organometallic-modified abrasive obtained by treatment of an unmodified abrasive (e.g., silica) with an organometallic compound can also be employed in this invention. Suitable organometallic compounds for modification include aluminum acetate, aluminum formate, and aluminum propionate. Suitable abrasives include, but are not limited to, colloidal products, fumed products, and mixtures thereof.

Silica or organometallic-modified silica is a preferred abrasive material used in the present invention. The silica may be, for example, colloidal silica, fumed silica and other silica dispersions; however, the preferred silica is colloidal silica.

The abrasive is present in the slurry in a concentration of about 0.001 weight % to about 30 weight % of the total weight of the slurry. In one embodiment, the abrasive is present in a concentration of about 0.01 weight % to about 5 weight %.

In embodiments of this invention having an oxidizing agent, the oxidizing agent can be any suitable oxidizing agent. Suitable oxidizing agents include, for example, one or more per-compounds, which comprise at least one peroxy group (—O—O—). Suitable per-compounds include, for example, peroxides, persulfates (e.g., monopersulfates and dipersulfates), percarbonates, and acids thereof, and salts thereof, and mixtures thereof. Other suitable oxidizing agents include, for example, oxidized halides (e.g., chlorates, bromates, iodates, perchlorates, perbromates, periodates, and acids thereof, and mixtures thereof, and the like), perboric acid, perborates, percarbonates, peroxyacids (e.g., peracetic acid, perbenzoic acid, m-chloroperbenzoic acid, salts thereof, mixtures thereof, and the like), permanganates, chromates, cerium compounds, ferricyanides (e.g., potassium ferricyanide), mixtures thereof, and the like. Preferred oxidizing agents include, for example, hydrogen peroxide, urea-hydrogen peroxide, sodium peroxide, benzyl peroxide, di-t-butyl peroxide, peracetic acid, monopersulfuric acid, dipersulfuric acid, iodic acid, and salts thereof, and mixtures thereof.

In compositions of this invention directed to metal CMP, (hydrogen peroxide) H₂O₂ is used as a preferred oxidizing agent. When used, preferably the concentration of the H₂O₂ is from about 0.2 weight % to about 5 weight % of the total weight of the slurry.

Other chemicals that may be added to the CMP slurry composition include, for example, water-miscible solvents, surfactants, pH adjusting agents, acids, additional corrosion inhibitors, fluorine-containing compounds, chelating agents, non-polymeric nitrogen-containing compounds, and salts.

Suitable water-miscible solvents that may be added to the slurry composition include, for example, ethyl acetate, methanol, ethanol, propanol, isopropanol, butanol, glycerol, ethylene glycol, and propylene glycol, and mixtures thereof. The water-miscible solvents may be present in the slurry composition in a concentration of about 0 weight % to about 4 weight % in one embodiment, of about 0.1 weight % to about 2.0 weight % in another embodiment, and, in a concentration of about 0.5 weight % to about 1.0 weight % in yet another embodiment; each of these weight % values is based on the total weight of the slurry. The preferred types of water-miscible solvents are isopropanol, butanol, and glycerol.

Suitable surfactant compounds that may be added to the slurry composition include, for example, any of the numerous nonionic, anionic, cationic or amphoteric surfactants known to those skilled in the art. The surfactant compounds may be present in the slurry composition in a concentration of about 0 weight % to about 1 weight % in one embodiment, of about 0.0005 weight % to about 1 weight % in another embodiment, and, in a concentration of about 0.001 weight % to about 0.5 weight % in yet another embodiment; each of these weight % values is based on the total weight of the slurry. The preferred types of surfactants are nonionic, anionic, or mixtures thereof and are most preferably present in a concentration of about 10 ppm to about 1000 ppm of the total weight of the slurry. Nonionic surfactants are most preferred. A preferred nonionic surfactant is Surfynol® 104E, which is a 50:50 weight percent mixture of 2,4,7,9-tetramethyl-5-decyn-4,7-diol and ethylene glycol, (Air Products and Chemicals, Inc. Allentown, Pa.).

The pH-adjusting agent is used to improve the stability of the polishing composition, to improve the safety in use or to meet the requirements of various regulations. As a pH-adjusting agent to be used to lower the pH of the polishing composition of the present invention, hydrochloric acid, nitric acid, sulfuric acid, chloroacetic acid, tartaric acid, succinic acid, citric acid, malic acid, malonic acid, various fatty acids, various polycarboxylic acids may be employed. On the other hand, as a pH-adjusting agent to be used for the purpose of raising the pH, potassium hydroxide, sodium hydroxide, ammonia, tetramethylammonium hydroxide, ethylenediamine, piperazine, polyethyleneimine, etc., may be employed. The polishing composition of the present invention is not particularly limited with respect to the pH, but it is usually adjusted to pH 3 to 10.

In metal CMP applications, compositions having slightly alkaline or neutral pH values are generally preferred according to this invention. In this case, a suitable slurry pH is from about 6.0 to about 8.5, preferably from about 7.0 to about 8.2, and more preferably, from about 7.2 to about 7.9.

Other suitable acid compounds that may be added (in place of or in addition to the pH-adjusting acids mentioned supra) to the slurry composition include, but are not limited to, formic acid, acetic acid, propanoic acid, butanoic acid, pentanoic acid, hexanoic acid, heptanoic acid, octanoic acid, nonanoic acid, lactic acid, hydrochloric acid, nitric acid, phosphoric acid, sulfuric acid, hydrofluoric acid, malic acid, tartaric acid, gluconic acid, citric acid, phthalic acid, pyrocatechoic acid, pyrogallol carboxylic acid, gallic acid, tannic acid, and mixtures thereof. These acid compounds may be present in the slurry composition in a concentration of about 0 weight % to about 5 weight % of the total weight of the slurry.

Carboxylic acids, if added, may also impart corrosion inhibition properties to the slurry composition.

Suitable additional corrosion inhibitors that may be added to the slurry composition include, for example, 1,2,4-triazole, benzotriazole, 6-tolylytriazole, tolyltriazole derivatives, 1-(2,3-dicarboxypropyl)benzotriazole, N-acyl-N-hydrocarbonoxyalkyl aspartic acid compounds, and mixtures thereof. The additional corrosion inhibitor may be present in the slurry in a concentration of about 0 ppm to about 4000 ppm in an embodiment, from about 10 ppm to about 4000 ppm in another embodiment, and from about 50 ppm to about 2000 ppm in yet another embodiment, all based on the total weight of the slurry.

To increase the selectivity of tantalum and tantalum compounds relative to silicon dioxide and carbon-doped oxides, fluorine-containing compounds may be added to the slurry composition. Suitable fluorine-containing compounds include, for example, hydrogen fluoride, perfluoric acid, alkali metal fluoride salt, alkaline earth metal fluoride salt, ammonium fluoride, tetramethylammonium fluoride, ammonium bifluoride, ethylenediammonium difluoride, diethylenetriammonium trifluoride, and mixtures thereof. The fluorine-containing compounds may be present in the slurry composition in a concentration of about 0 weight % to about 5 weight % in an embodiment, from about 0.65 weight % to about 5 weight % in another embodiment, and from about 0.50 weight % to about 2.0 weight % in yet another embodiment, all based on the total weight of the slurry. A suitable fluorine-containing compound is ammonium fluoride.

Suitable chelating agents that may be added to the slurry composition include, but are not limited to, ethylenediaminetetracetic acid (EDTA), N-hydroxyethylethylenediaminetriacetic acid (NHEDTA), nitrilotriacetic acid (NTA), diethylenetriaminepentacetic acid (DPTA), ethanoldiglycinate, glycine, tricine, and mixtures thereof. The chelating agents may be present in the slurry composition in a concentration of about 0 weight % to about 3 weight % in one embodiment, and in a concentration of about 0.5 weight % to about 2.0 weight % in another embodiment based on the total weight of the slurry. Preferred chelating agents are glycine, tricine and EDTA. When present, a chelating agent is usually present in a concentration of about 0.5 weight % to about 2.0 weight % of the total weight of the slurry.

Suitable non-polymeric nitrogen-containing compounds (amines, hydroxides, etc.) that may be added to the slurry composition include, for example, ammonium hydroxide, hydroxylamine, monoethanolamine, diethanolamine, triethanolamine, diethyleneglycolamine, N-hydroxylethylpiperazine, and mixtures thereof. These non-polymeric nitrogen-containing compounds may be present in the slurry composition in a concentration of about 0 weight % to about 1 weight %, and, if present, are normally present at a level of about 0.01 weight % to about 0.20 weight % of the total weight of the slurry. A preferred non-polymeric nitrogen-containing compound is ammonium hydroxide and is most preferably present in a concentration of about 0.01 weight % to about 0.1 weight % of the total weight of the slurry.

Suitable salts that optionally may be added to the slurry composition include, for example, ammonium persulfate, potassium persulfate, potassium sulfite, potassium carbonate, ammonium nitrate, potassium hydrogen phthalate, hydroxylamine sulfate, and mixtures thereof. The salts may be present in the slurry composition in a concentration of about 0 weight % to about 10 weight %, and, if present, are normally present at a level of about 0.02 weight % to about 5 weight % of the total weight of the slurry.

Still other chemicals that can be added to the slurry compositions are biological agents such as bactericides, biocides and fungicides especially if the pH is around about 6 to 9. Suitable biocides, include, but are not limited to, 1,2-benzisothiazolin-3-one; 2(hydroxymethyl)amino ethanol; 1,3-dihydroxymethyl-5,5-dimethylhydantoin; 1-hydroxymethyl-5,5-dimethylhydantion; 3-iodo-2-propynyl-butylcarbamate; glutaraldehyde; 1,2-dibromo-2,4-dicyanobutane; 5-chloro-2-methyl-4-isothiazoline-3-one; 2-methyl-4-isothiazolin-3-one; and mixtures thereof. Preferred biocides are isothiazolines and benzisothiazolines. When present, a biocide is usually present in a concentration of about 0.001 weight % to about 0.1 weight % of the total weight of the slurry.

Associated Methods

The associated methods of this invention entail use of the aforementioned composition (as disclosed supra) for chemical mechanical planarization of substrates comprised of metals and dielectric materials. In the methods, a substrate (e.g., a wafer) is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to effect the removal of material to planarize the substrate.

The composition and associated methods of this invention are effective for CMP of a wide variety of substrates, including substrates having dielectric portions that comprise materials having dielectric constants less than 3.3 (low-k materials). Suitable low-k films in substrates include, but are not limited to, organic polymers, carbon-doped oxides, fluorinated silicon glass (FSG), inorganic porous oxide-like materials, and hybrid organic-inorganic materials. Representative low-k materials and deposition methods for these materials are summarized below.

| | | Deposition | |
|---|---|---|---|
| Vendor | Trade Name | Method | Material |
| Air Products and Chemicals | MesoElk ® | Spin-on | Hybrid organic-inorganic |
| Applied Materials | Black Diamond | CVD | Carbon-doped oxide |
| Dow Chemical | SiLK ™, Porous SiLK ™ | Spin-on | Organic polymer |
| Honeywell Electronic Materials | NANOGLASS ® E | Spin-on | Inorganic oxide-like |
| Novellus Systems | CORAL ® | PECVD | Carbon-doped oxide |

PECVD = Plasma enhanced chemical vapor deposition
CVD = chemical vapor deposition

Similarly, the composition and associated methods of this invention are effective for CMP of substrates comprised of various metals, including, but not limited to, tantalum, titanium, tungsten, copper and noble metals.

The present invention is further demonstrated by the examples below.

### Glossary

Components

A) TINUVIN® compounds: TINUVIN® is a trade name for a family of alkyl-substituted phenol compounds containing benzotriazole moieties, that are supplied by Ciba Specialty Chemicals Corporation, 540 White Plains Road, Tarrytown, N.Y. 10591. The chemical names (and structures in certain cases) of various TINUVIN® compounds are summarized below:
1) TINUVIN 328: 2-(2H-benzotriazol-2-yl)-4,6-ditertpentylphenol 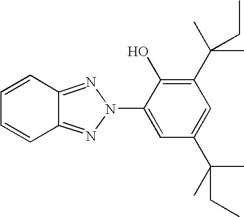
2) TINUVIN 234: 2-(2H-benzotriazol-2-yl)-4,6-bis(1-methy-1-phenylethyl)phenol
3) TINUVIN P: Phenol, 2-(2H-benzotriazol-2-yl)-4-methyl- 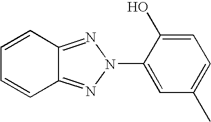
4) TINUVIN 326: Phenol, 2-(5-chloro-2H-benzotriazol-2-yl)-6-(1,1-dimethylethyl)-4-methyl- 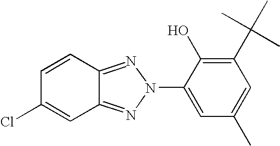
5) TINUVIN 109: A mixture of 45-55 weight % of Benzenepropanoic acid, 3-(5-chloro-2H-benzotriazol-2-yl)-5-(1,1-dimethylethyl)-4-hydroxy, octyl ester and 45-55 weight % of Benzenepropanoic acid, 3-(5-chloro-2H-benzotriazol-2-yl)-5-(1,1-dimethylethyl)-4-hydroxy-, 2-ethylhexyl ester 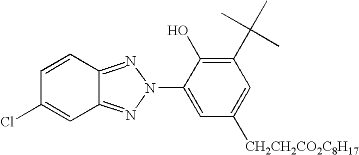
6) TINUVIN 384-2: A mixture of 90-100 weight % Benzenepropanoic acid, 3-(2H-benzotriazol-2-yl)-5-(1,1-dimethylethyl)-4-hydroxy-, C7-9-branched alkyl esters and 3-10 weight % of 2-(1-methoxy)propyl acetate 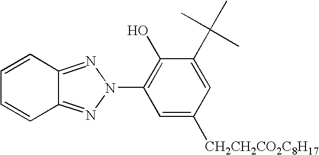
7) TINUVIN 329: 2-(2-Hydroxy-5-(tert)-octylphenyl)benzotriazole. 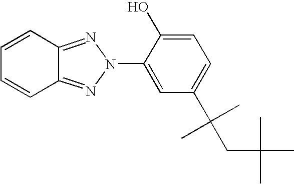
8) TINUVIN 213: A mixture of 30-45 weight % of Poly(oxy-1,2-ethanediyl), .alpha.-[3-[3-(2H-benzotriazol-2-yl)-5-(1,1-dimethylethyl)-4-hydroxyphenyl]-1-oxopropyl]-.omega.-[3-[3-(2H-benzotriazol-2-yl)-5-(1,1-dimethylethyl)-4-hydroxyphenyl]-1-oxopropyl]-, and 40-55 weight % of Poly(oxy-1,2-ethanediyl), .alpha.-[3-[3-(2H-benzotriazol-2-yl)-5-(1,1-dimethylethyl)-4-hydroxyphenyl]-1-oxopropyl) -.omega.-hydroxy-, and 10-16 weight % of Poly(oxy-1,2-ethanediyl), .alpha.-hydro-.omega.-hydroxy- 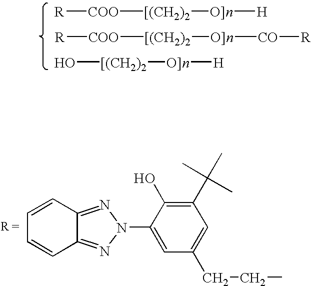
9) TINUVIN 99-2: A mixture of 90-100 weight % Benzenepropanoic acid, 3-(2H-benzotriazol-2-yl)-5-(1,1-dimethylethyl)-4-hydroxy-, C7-9-branched alkyl esters and 3-10 weight % of 2-(1-methoxy)propyl acetate

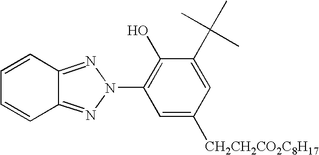

B) Other co-additives with TINUVIN® compounds in the polishing compositions: A list of other additives used in the polishing formulations is summarized below:
1) Potassium stabilized colloidal silica: Poliedge 2001®, an approximately 50 weight % dispersion in water: Air Products and Chemicals, Inc., 7201 Hamilton Blvd. Allentown, Pa. 18195-1501.
2) Proxel® GXL: Avecia Inc, 1405 Foulk Road, Wilmington, Del. 19850-5457; main component from MSDS is 1,2-benzisothiazolin-3-one.
3) 1,2,4-Triazole: Atofina, Basic Chemicals, 200-Market Street, Philadelphia, Pa. 19103.
4) Glycine: Spectrum Chemicals, 14422 S. San Pedro Street, Gardena, Calif. 90248
5) Glycerol: Acros Organics, One Reagent Street Lane, Fairlawn, N.J. 07410.
6) Benzotriazole: Aldrich Chemical Company, Inc., 1001 West St. Paul, Milwaukee, Wis. 53233.
7) Isopropanol: Aldrich Chemical Company, Inc., 1001 West St. Paul, Milwaukee, Wis. 53233.

C) General

| | |
|---|---|
| PETEOS | Plasma enhanced deposition of tetraethoxy silane; a dielectric |
| | oxide layer. |
| Pattern Wafers | MIT 854-type mask wafers were procured from Advantiv |
| | Technologies, Inc.; 5000 Hopyard Road, Suite 318, Pleasantan, |
| | CA 94588 for characterizing the impact of slurry formulations on |
| | their planarity response. The product identification of the wafers |
| | used for these characterizations was CMP431. A description of |
| | these wafers includes 0.25 μm trench (M1) etched through 5K Å |
| | PETEOS to 1K Å PE-SiN over 5.5K Å oxide 250 Ta/1K Å Cu seed, |
| | 10K Å CuE fill (annealed). A detailed description of the MIT 854 |
| | mask can be obtained from the following document: |
| | “MIT/Sematech 854 AZ Copper on Low-K Chemical Mechanical |
| | Polishing (CMP) Characterization Test Chip” obtained from |
| | International Sematech, Inc. |
| Planarity: | Planarity refers to terms such as dishing and erosion which are |
| | measured on patterned wafers such as MIT 854 mask. Layout of |
| | the features is available in the publication from Sematech. Erosion |
| | typically is measured on 9/1 or 0.25/0.25 features. A 100/100 |
| | feature implies a feature with an array of 100 μm Cu trenches |
| | (“lines”) patterned at a pitch of 200 μm, etched and then |
| | electrochemically plated. Thus, the center of one 100 μm Cu line is |
| | separated from the next by 200 μm leaving a 100 μm space of |
| | either PETEOS or Ta over PETEOS or Cu over Ta over PETEOS |
| | between two 100 μm Cu lines. Similarly, a 9/1 feature implies a |
| | feature with 9 μm Cu lines separated by 1 μm of space, and a pitch |
| | of 10 μm between two 9 μm Cu lines. A 0.25/0.25 feature implies |
| | 0.25 μm Cu lines separated by 0.25 μm space, and a pitch of 0.5 μm |
| | between two 0.25 μm Cu lines. |
| Blanket Wafers: | Blanket wafers are those that have typically one type of surface |
| | prepared for polishing experiments. These are either |
| | electrochemically deposited copper, PVD tantalum or PETEOS. |
| | The blanket wafers used in this work were purchased from Silicon |
| | Valley Microelectronics, 1150 Campbell Ave, CA, 95126. The film |
| | thickness specifications are summarized below. |
| IC1010 ™ Pad | Rohm and Haas Electronic Materials IC1010 ™ pads were used for |
| | step I copper CMP. The IC1010 ™ pad consists of a rigid |
| | microporous polyurethane with a radial grooving pattern top pad |
| | and a Suba ™ IV impregnated felt sub-pad. Rohm and Haas |
| | Electronic Materials is based in Newark, DE. |

General
Å: angstrom(s)—a unit of length
CMP: chemical mechanical planarization, or chemical mechanical polishing
min: minute(s)
ml: milliliter(s)
psi: pounds per square inch

rpm: revolutions per minute

Dishing Parameters/Terms

| | |
|---|---|
| Anti-dishing Agent | A compound added to a polishing slurry to reduce the amount of |
| | dishing of metal features during CMP processing. |
| Dishing delta for | The dishing delta was calculated by the difference in dishing |
| 100/100 features | values measured before and after CMP processing with a slurry |
| at the center die | formulation. The measurements were conducted on a P-15 |
| | Surface Profiler for the 100/100 features at the same specific die |
| | location at the center of a MIT 854-type mask copper pattern |
| | wafer. |
| Dishing delta for | The dishing delta was calculated by the difference in dishing |
| 100/100 features | values measured before and after CMP processing with a slurry |
| at the edge die | formulation. The measurements were conducted on a P-15 |
| | Surface Profiler for the 100/100 features at the same specific die |
| | location at the edge of a MIT 854-type mask copper pattern wafer. |
| Average dishing | Average dishing delta refers to the average value calculated from |
| delta | the calculated dishing delta for the 100/100 features at both the |
| | center-die and edge-die locations on a MIT 854-type mask copper |
| | pattern wafer. |
| Dishing Values | (See discussion infra on dishing measurements/values) |

### EXAMPLES

General

All percentages are weight percentages and all temperatures are degrees Centigrade unless otherwise indicated.

Chemical Mechanical Planarization (CMP) Methodology

In the examples presented below, chemical mechanical planarization (CMP) experiments were run using the procedures and experimental conditions given below.

Metrology

PETEOS thickness was measured with a Nanometrics, model, # 9200, manufactured by Nanometrics Inc, 1550 Buckeye, Milpitas, Calif. 95035-7418. The metal films were measured with a ResMap CDE, model 168, manufactured by Creative Design Engineering, Inc, 20565 Alves Dr, Cupertino, Calif., 95014. This tool is a four-point probe sheet resistance tool. Twenty-five and forty nine-point polar scans were taken with the respective tools at 3-mm edge exclusion. Planarity measurements were conducted on a P-15 Surface Profiler manufactured by KLA® Tencore, 160 Rio Robles, San Jose, Calif. 95161-9055.

CMP Tool

The CMP tool that was used is a Mirra®, manufactured by Applied Materials, 3050 Boweres Avenue, Santa Clara, Calif., 95054. A Rohm and Haas Electronic Materials IC1010™ pad, supplied by Rohm and Haas Electronic Materials, 3804 East Watkins Street, Phoenix, Ariz., 85034, was used on the platen for the blanket wafer studies.

The Mirra® tool mid-point conditions for polishing blanket wafers were:

| | polishing blanket | | polishing blanket | |
|---|---|---|---|---|
| | wafers at 2 psi | | wafers at 1 psi | |
| Platen speed | 119 | rpm | 119 | rpm |
| Head speed | 134 | rpm | 134 | rpm |
| Inner tube pressure | 2.2 | psi | Vented | |
| Retaining ring pressure | 2.5 | psi | 1.5 | psi |
| Membrane pressure | 2.0 | psi | 1.0 | psi |
| Slurry flow rate | 200 | ml/min | 200 | ml/min |
| Polish time | 60 | seconds | 60 | seconds |

Dishing Measurements using Patterned Copper Wafers

Dishing is defined as the difference between the field dielectric material level (for example, PETEOS) or barrier material level (for example, tantalum and or tantalum nitride) of a wafer and the lowest point within the copper line of the wafer after executing a CMP process on the wafer. The pattern wafer studies described in Examples 1-11 below, used pre-cleared CMP431 copper pattern wafers that had previously had the copper overburden removed such that the pattern wafer surface was primarily barrier material with copper inside the patterned lines. The impact of the slurry formulation on average dishing delta was determined by subjecting the pre-cleared CMP431 copper pattern wafers to CMP processing under comparable polishing conditions for a duration of 30 seconds with each slurry formulation. The dishing values were determined in the following manner. Dishing values were measured on the pre-cleared CMP431 copper pattern wafers using a P-15 Surface Profiler for the 100/100 features at the center-die and edge-die locations before polishing with the slurry formulations described in Examples 1-11. These values were typically between 600 Å to 1200 Å. The wafers were then processed on a Mirra® CMP tool. After processing with the slurry formulations described in Examples 1-11 of this invention, the dishing values were measured again using a P-15 Surface Profiler for the 100/100 features at the same center-die and edge-die locations. The dishing delta was calculated by the difference in dishing values measured before and after CMP processing. The dishing delta for 100/100 features at the edge die, and the dishing delta for 100/100 features at the center die, were then averaged to determine the average dishing delta for each slurry formulation described in Examples 1-11. These average dishing delta values for 100/100 features are listed in Tables 1 and 2.

Examples 12-14 used new, patterned copper wafers as received from the vendor; the results obtained in these examples are shown in Table 3.

Blanket Wafers

Polishing experiments were conducted using electrochemically deposited Black Diamond®, copper, PETEOS, tantalum, and tantalum nitride wafers. These blanket wafers were purchased from Silicon Valley Microelectronics, 1150 Campbell Ave, Calif. 95126. The film thickness specifications are summarized below:
Black Diamond®: 5,000 Å (on silicon)
Copper: 10,000 Å electroplated copper/1,000 Å copper seed/250 Å Ta (on silicon)
PETEOS: 15,000 Å on silicon
Tantalum: 2000 Å on 5,000 Å thermal oxide (on silicon)
Tantalum nitride: 3000 Å on 3,000 Å thermal oxide (on silicon)
   Polishing of Copper Pattern Wafers

The (new and pre-cleared) CMP431 copper pattern wafers were processed on the Mirra® tool configured with a IC1010™ pad described earlier. The process conditions were the following: membrane pressure 1.0 psi, retaining ring pressure 1.5 psi, inner tube pressure vented. The platen speed was 119 rpm; the head speed was 134 rpm. The slurry flow was 200 ml/min. The wafers were processed for 30 seconds.

### Examples

### Examples 1-6

These examples illustrate the effect of adding TINUVIN® compounds to polishing formulations on the average dishing delta of copper pattern wafers and copper removal rates measured on blanket wafers at 2.0 psi and 1.0 psi. In Example 1 (comparative example without a TINUVIN® compound), a procedure for the preparation of a polishing formulation is described. Example 2 contains TINUVIN P; Examples 3 and 4 contain different concentrations of TINUVIN 328; Example 5 contains TINUVIN 329; and Example 6 (comparative) contains a commonly used anti-dishing agent—specifically benzotriazole.

### Example 1 (Comparative)

### Comparative Experiment, no TINUVIN® Compound Added

A 1.0 kilogram batch of the slurry was prepared for each polishing experiment. The components, and a procedure for the preparation of the polishing composition is described below:

Components of the Polishing Composition:

1) Colloidal silica, Poliedge 2001®=2.0 grams
2) Glycine=13.0 grams
3) 1,2,4-Triazole=1.5 grams
4) Isopropanol=10.0 grams
5) Glycerol=10.0 grams
6) Potassium hydroxide=30 ppm
7) Deionized water=963.5 grams
   Procedure for Mixing the Slurry, 1.0 ka Batch Size

In a 2-liter beaker, 963.5 grams of de-ionized water were transferred. After adding water to the beaker, it was kept under agitation using a magnetic stirrer. Under agitation, 2.0 grams of colloidal silica, Poliedge 2001®, were added slowly during a period of 3 minutes. After completing the addition of the colloidal silica (sol), 13.0 grams of glycine were added during a period of 4 minutes to the silica sol mixture. The mixture was agitated for an additional 4 minutes. After 4 minutes of agitation, under agitation, 10 grams of isopropanol, followed by the addition of 10 grams of glycerol was completed; this step took between 2 to 3 minutes. After stirring the mixture for 4 minutes, 1.5 grams of 1,2,4-Triazole were added under agitation. The contents of the mixture were agitated for additional 4 minutes followed by the addition of 30 ppm potassium hydroxide. Stirring was continued for additional 10 minutes to give a uniform dispersion, the pH of the polishing mixture was 7.37.

This composition described in Example 1 was used to polish copper pattern wafers. The results of the polishing experiments such as copper removal rate at 2.0 psi, copper removal rate at 1.0 psi, and average dishing delta are summarized in Table 1.

### Example 2

### TINUVIN P in Polishing Composition

Compared to the formulation described in Example 1, in Example 2 the concentration of the components were kept the same except 100 ppm of TINUVIN P was included in the composition of this example. The TINUVIN P was added as a solution in isopropanol. TINUVIN P was supplied by Ciba Specialty Chemicals Corporation, 540 White Plains Road, Tarrytown, N.Y. 10591. During polishing experiments, the Example 2 formulation containing 100 ppm of TINUVIN P coated the pad and pad conditioner, and afforded low copper removal rates at 2.0 psi and 1.0 psi with heavy scratching on the copper wafer; the data obtained is shown in Table 1. The TINUVIN P essentially was insoluble in the polishing composition at 100 ppm, 50 ppm or 25 ppm concentration levels. More specifically, essentially none of the TINUVIN P appeared to dissolve with stirring and heating when 100 ppm, 50 ppm or 25 ppm of TINUVIN P were added to slurry samples containing the other components of the composition of Example 1 (Comparative). Furthermore, upon filtering, the filtrate did not exhibit a UV spectrum characteristic of TINUVIN P, indicating essentially near complete insolubility in this aqueous based slurry. TINUVIN P does not contain a branched C₄-C₁₄ alkyl group nor a branched C₄-C₁₄ aralkyl group.

### Examples 3 and 4

### TINUVIN 328 as an Anti-Dishing Agent

In Examples 3 and 4, the composition was the same as described in the comparative Example 1, except that in addition TINUVIN 328 (supplied by Ciba Specialty Chemicals Corporation, 540 White Plains Road, Tarrytown, N.Y. 10591) was present at 20 ppm (Example 3) and 100 ppm (Example 4) concentration levels, respectively. The TINUVIN 328 was added as a solution in isopropanol. The Example 3 and 4 compositions were used to polish copper pattern wafers; the results of the polishing experiments such as copper removal rate at 2.0 psi, copper removal rate at 1.0 psi, and average dishing delta are summarized in Table 1.

### Example 5

### TINUVIN 329 as an Anti-Dishing Agent

In Example 5, the composition was the same as described in the comparative Example 1, except that in addition TINUVIN 329 (supplied by Ciba Specialty Chemicals Corporation, 540 White Plains Road, Tarrytown, N.Y. 10591) was present at 100 ppm concentration level. The TINUVIN 329 was added as a solution in isopropanol. The Example 5 composition was used to polish copper pattern wafers; the results of the polishing experiments such as copper removal rate at 2.0 psi, copper removal rate at 1.0 psi, and average dishing delta are summarized in Table 1.

### Example 6 (Comparative)

### Benzotriazole in the Polishing Composition

The composition tested in Example 6 was the same as that in Comparative Example 1 except that in addition benzotriazole was present at a concentration level of 100 ppm. Benzotriazole, supplied by Aldrich Chemical Company, Inc., 1001 West St. Paul, Milwaukee, Wis., 53233, is a known component in prior art chemical mechanical planarization formulations. The Example 6 polishing composition was used to polish copper pattern wafers; the results of the polishing experiments such as copper removal rate at 2.0 psi, copper removal rate at 1.0 psi, and average dishing delta are summarized in Table 1.

### Discussion of Examples 1-6

Key results for Examples 1-6 are summarized in Table 1, which include copper removal rates at 2.0 psi, copper removal rates at 1.0 psi, and average dishing delta. In Table 1, Examples 1, 2, and 6 are comparative whereas Examples 3, 4, and 5 show how the addition of TINUVIN 328 at two different concentrations (Examples 3 and 4), or TINUVIN 329 (Example 5) affect copper removal rates and average dishing delta. For instance, Example 1 (comparative) with neither TINUVIN 328 nor TINUVIN 329 has copper removal rates of 7812 Å/min at 2.0 psi, 3959 Å/min at 1.0 psi, and average dishing delta of 620 Å. In Examples 4 and 5, TINUVIN 328 and TINUVIN 329 were added to the polishing formulations at 100 ppm concentration levels, respectively. As shown in Table 1, the formulation in Example 4 gave copper removal rates of 7764 Å/min at 2.0 psi, 3912 Å/min at 1.0 psi, and average dishing delta of 210 Å whereas the formulation in Example 5 gave copper removal rates of 6911 Å/min at 2.0 psi, 3801 Å/min at 1.0 psi, and average dishing delta of 80 Å.

Clearly data show that addition of TINUVIN 328 or TINUVIN 329 decreased average dishing delta from 620 Å to 337 Å (Example 4) and 80 Å (Example 5). A remarkable advantage of adding TINUVIN 328 or TINUVIN 329 to the polishing formulation was that the polishing formulations maintained high removal rates at 1.0 psi and 2.0 psi whilst the average dishing delta reduced dramatically from 620 Å to 210 Å (Example 4) and 80 Å (Example 5). Interestingly, Example 2 (comparative) containing TINUVIN P failed to show any improvement in average dishing delta; this behavior is believed to be due to the total or near total insolubility of TINUVIN P in the polishing formulation. During polishing experiments, the insoluble TINUVIN P compound coated the pad and pad conditioner; this undesirable coating on the pad and pad conditioner led to low copper removal rates of 5685 Å/min at 2.0 psi and 2688 Å/min at 1.0 psi and left TINUVIN P residue on the copper line. Consequently, in this case, the average dishing delta value was rendered meaningless to report.

As shown in Table 1, Example 6 (comparative) with benzotriazole was also included as the use of benzotriazole as a component in polishing formulations is known in the prior art. Clearly, as expected and known in the prior art, the data shows that the use of benzotriazole reduced average dishing delta from 620 Å to 168 Å; however, this led to a considerable reduction in copper removal rates. The copper removal rates were 3596 Å/min at 2.0 psi and 903 Å/min 1.0 psi. Comparison of the copper removal rates and average dishing delta for TINUVIN 328 or TINUVIN 329 containing slurry formulations versus comparative Examples 1, 2, and 6, shows a desired combination of TINUVIN 328 or TINUVIN 329 providing both a low average dishing delta combined with maintaining high copper removal rates at 2.0 psi and 1.0 psi.

As shown in Table 1, Example 3 contains 20 ppm of TINUVIN 328, whereas Example 4 contains 100 ppm of TINUVIN 328. Clearly, the polishing data suggest that as the concentration of TINUVIN 328 increased from 25 ppm to 100 ppm, average dishing delta decreased from 337 Å to 210 Å while maintaining the same high copper removal rates at 2.0 psi (7789 Å/min for Example 3 versus 7764 Å/min for Example 4) and 1.0 psi (3419 Å/min for Example 3 versus 3912 Å/min for Example 4.)

### Examples 7-11

Examples 7-11 illustrate the effect of adding various TINUVIN® compounds to polishing formulations on copper removal rates measured on blanket wafers at 2.0 psi and 1.0 psi, and average dishing delta of copper pattern wafers, at fixed concentration of colloidal silica (Poliedge 2001®, 0.04 weight %), 1,2,4-triazole (0.15 weight %) and glycine (2.0 weight %). Compared to Examples 1-6 in Table 1, the concentration of Poliedge 2001® in Examples 7-11 was decreased from 0.2 weight % to 0.04 weight %, and the concentration of glycine was increased from 1.3 weight % to 2.0 weight %. The polishing compositions were prepared using the same procedure as described in Example 1 except that the only differences were in the amount of glycine, the amount of colloidal silica, and the choice of particular of TINUVIN® compound. The TINUVIN® compounds were added as a solution in isopropanol. As shown in Table 2, maintaining glycine (2.0 weight %), Poliedge 2001® (0.04 weight %), and 1,2,4-triazole (0.15 weight %) constant, the following TINUVIN® compounds were evaluated under comparable conditions as described in Examples 7-11:

Example 7: The formulation of this example contains 100 ppm of TINUVIN 328.

Examples 8 and 9: The formulations of these examples (8 and 9) contain 100 ppm and 150 ppm of TINUVIN 213, respectively.

Example 10: The formulation of this example contains 100 ppm of TINUVIN 109.

Example 11: The formulation of this example contains 100 ppm of TINUVIN 384-2. The polishing data obtained in these examples which include copper removal rates at 2.0 psi, copper removal rates at 1.0 psi, and average dishing delta are summarized in Table 2.

### Discussion of Examples 7-11

Key results for Examples 7-11 are summarized in Table 2, which include copper removal rates at 2.0 psi, copper removal rates at 1.0 psi, and average dishing delta. Compared to Examples 1-6 in Table 1, Examples 7-11 in Table 2 illustrate the effect of adding different TINUVIN® compounds, such as TINUVIN 328, TINUVIN 213, TINUVIN 109, and TINUVIN 384-2, on copper removal rates and average dishing delta at fixed concentration of Poliedge 2001® (0.04 weight %), 1,2,4-triazole (0.15 weight %) and glycine (2.0 weight %). Thus, compared to Examples 1-6 in Table 1, for all Examples 7-11 in Table 2, the concentration of abrasive was decreased from 0.1 weight % to 0.02 weight %, and glycine was increased from 1.3 weight % to 2.0 weight percent.

As shown in Table 2, the polishing results indicate that TINUVIN 328, TINUVIN 213, TINUVIN 109, and TINUVIN 384-2 gave low average dishing delta while maintaining high copper removal rates at 2.0 psi and 1.0 psi. Of the seven TINUVIN® compounds evaluated and shown in Tables 1 and 2, TINUVIN 328 and TINUVIN 329 afforded the lowest average dishing delta values while still having high copper removal rates at 2.0 psi and 1.0 psi.

### Examples 12-14

The polishing compositions for Examples 12-14 are shown in Table 3. These polishing formulations were prepared using the same procedure as described in Examples 1 and 2; the only difference was that polishing experiments were conducted using new copper pattern wafers as received from the vendor instead of using pre-cleared copper pattern wafers. As a result of this change, instead of using average dishing delta values, as reported in Tables 1 and 2, absolute dishing values were measured for Examples 12-14 on 100/100 features at 1.0 psi. The TINUVIN 328 was added as a solution in isopropanol. Unlike Examples 12 and 13, Example 14 contains a biocide, Proxel® GXL, in the polishing formulation.

### Discussion of Examples 12-14

Key results for Examples 12-14 are summarized in Table 3, which includes copper removal rates at 2.0 psi and 1.0 psi, and absolute dishing values at 100/100 features. In Table 3, Example 12 is a comparative example formulation without a TINUVIN® compound, whereas Example 13 shows how addition of TINUVIN 328 affects copper removal rates, and absolute dishing at 100/100 features. In Table 3, Example 14 contains a biocide, Proxel® GXL, together with TINUVIN 328.

Clearly polishing results from Examples 12-14 suggest that the addition of TINUVIN 328 reduces absolute dishing at 100/100 features from 735 Å (comparative Example 12) to 320 Å without affecting copper removal rates at 2.0 psi and 1.0 psi. Interestingly, addition of Proxel® GXL has a synergistic effect in reducing absolute dishing in combination with TINUVIN 328; more specifically, addition of Proxel® GXL reduced absolute dishing from 320 Å (Example 13) to 254 Å (Example 14) without affecting copper removal rates at 1.0 psi. As seen in the glossary, the main component in Proxel® GXL is 1,2-benzisothiazolin-3-one.

Example 15: Effect of TINUVIN 328 on the polishing rates of tantalum, tantalum nitride, TEOS, and Black Diamond®

The polishing composition for Examples 15 is shown in Table 4. This polishing formulation was prepared using the same procedure as described in Examples 13. The TINUVIN 328 was added as a solution in isopropanol. The slurry was used to polish Black Diamond®, copper, PETEOS, tantalum, and tantalum nitride blanket wafers at 1.0 psi. The polishing results are also tabulated in Table 4. Clearly polishing results suggest that TINUVIN 328® maintains very low removal rates of PETEOS, tantalum, tantalum nitride, and Black Diamond® films, whilst achieving high copper removal rates.

TABLE 1
Effect of TINUVIN P, TINUVIN 328, TINUVIN 329, and Benzotriazole on Copper
Removal Rates and Average Dishing Delta.

| | | Example 2 | Example 3: | Example 4: | Example 5: | Example 6 |
|---|---|---|---|---|---|---|
| | Example 1 | Comparative: | TINUVIN | TINUVIN | TINUVIN | Comparative: |
| | Comparative: | TINUVIN P | 328 | 328 | 329 | Benzotriazole |
| | No TINUVIN | 100 ppm | 20 ppm | 100 ppm | 100 ppm | 100 ppm |
| Poliedge | 0.2 | 0.2 | 0.2 | 0.2 | 0.2 | 0.2 |
| 2001 ® | | | | | | |
| (weight %) | | | | | | |
| 1,2,4- | 0.15 | 0.15 | 0.15 | 0.15 | 0.15 | 0.15 |
| Triazole | | | | | | |
| (weight %) | | | | | | |
| Glycine | 1.3 | 1.3 | 1.3 | 1.3 | 1.3 | 1.3 |
| (weight %) | | | | | | |
| Glycerol | 1.0 | 1.0 | 1.0 | 1.0 | 1.0 | 1.0 |
| (weight %) | | | | | | |
| Potassium | 30 | 30 | 30 | 30 | 30 | 30 |
| hydroxide | | | | | | |
| (ppm) | | | | | | |
| H₂O₂ | 1.0 | 1.0 | 1.0 | 1.0 | 1.0 | 1.0 |
| (weight %) | | | | | | |
| Isopropanol | 1.0 | 1.0 | 1.0 | 1.0 | 1.0 | 1.0 |
| (weight %) | | | | | | |
| Water | balance | balance | balance | Balance | balance | balance |
| pH | 7.37 | 7.32 | 7.33 | 7.38 | 7.33 | 7.37 |
| Copper | 7812 | 5685 | 7789 | 7764 | 6911 | 3596 |
| removal rate | | | | | | |
| at 2.0 psi | | | | | | |
| (Å/min) | | | | | | |
| Copper | 3959 | 2688 | 3419 | 3912 | 3801 | 903 |
| removal rate | | | | | | |
| at 1.0 psi | | | | | | |
| (Å/min) | | | | | | |
| Average | 620 | ## | 337 | 210 | 80 | 168 |
| dishing delta | | | | | | |
| for 100/100 | | | | | | |
| features (Å) | | | | | | |

##: Due to complete or nearly complete insolubility of TINUVIN P in the Example 2 polishing formulation, quantitative polishing results cannot be reported.

TABLE 2
Effect of TINUVIN 328, TINUVIN 213, TINUVIN 109, and TINUVIN 384-2 on
Copper Removal Rates and Average Dishing Delta.

| | | Example 8: | | Example 10: | |
|---|---|---|---|---|---|
| | Example 7: | TINUVIN | Example 9: | TINUVIN | Example 11: |
| | TINUVIN 328 | 213 | TINUVIN 213 | 109 | TINUVIN 384-2 |
| | 100 ppm | 100 ppm | 150 ppm | 100 ppm | 100 ppm |
| Poliedge 2001 ® | 0.04 | 0.04 | 0.04 | 0.04 | 0.04 |
| (weight %) | | | | | |
| 1,2,4-Triazole | 0.15 | 0.15 | 0.15 | 0.15 | 0.15 |
| (weight %) | | | | | |
| Glycine | 2.0 | 2.0 | 2.0 | 2.0 | 2.0 |
| (weight %) | | | | | |
| Glycerol | 1.0 | 1.0 | 1.0 | 1.0 | 1.0 |
| (weight %) | | | | | |
| Potassium | 47 | 47 | 47 | 47 | 47 |
| hydroxide (ppm) | | | | | |
| H₂O₂ | 1.0 | 1.0 | 1.0 | 1.0 | 1.0 |
| (weight %) | | | | | |
| Isopropanol | 1.0 | 1.0 | 1.0 | 1.0 | 1.0 |
| (weight %) | | | | | |
| Water | Balance | balance | Balance | balance | balance |
| (weight %) | | | | | |
| pH | 7.39 | 7.4 | 7.33 | 7.38 | 7.38 |
| Copper removal rate at 2.0 psi | 6351 | 6714 | 6535 | 6301 | 6323 |
| (Å/min) | | | | | |
| Copper removal rate at 1.0 psi | 2942 | 3542 | 3438 | 3156 | 2475 |
| (Å/min) | | | | | |
| Average dishing delta for | 87 | 176 | 122 | 134 | 125 |
| 100/100 features (Å) | | | | | |

TABLE 3
Effect of TINUVIN 328 ® and Proxel ® GXL on Copper Removal Rates and
Absolute Dishing Values of 100/100 Features.

| | | | Example 14: |
|---|---|---|---|
| | | | TINUVIN 328 |
| | Example 12 | Example 13: | 100 ppm and |
| | Comparative: | TINUVIN 328 | Proxel ® GXL |
| | No TINUVIN | 100 ppm | 200 ppm |
| Poliedge 2001 ® (weight %) | 0.2 | 0.2 | 0.2 |
| 1,2,4-Triazole (weight %) | 0.15 | 0.15 | 0.15 |
| Glycine (weight %) | 1.3 | 1.3 | 1.3 |
| Glycerol (weight %) | 1.0 | 1.0 | 1.0 |
| Potassium hydroxide (ppm) | 30 | 30 | 30 |
| Proxel, GXL (weight %) | | | 0.02 |
| Isopropanol (weight %) | 1.0 | 1.0 | 1.0 |
| H₂O₂ (weight %) | 1.0 | 1.0 | 1.0 |
| Water | balance | balance | balance |
| pH | 7.37 | 7.32 | 7.38 |
| Copper removal rate at 2.0 psi (Å/min) | 7238 | 7330 | 6910 |
| Copper removal rate at 1.0 psi (Å/min) | 3515 | 3368 | 3497 |
| Dishing at 100/100 features; average of center-die, | 735 | 320 | 254 |
| center-middle-die, middle-edge-die, and | | | |
| edge-die (Å). | | | |

TABLE 4
Effect of TINUVIN 328 on the Removal Rates of Black
Diamond ®, Copper, PETEOS, Ta, and TaN Films

| | Example 15: |
|---|---|
| | TINUVIN-328 |
| Poliedge 2001 ® (weight %) | 0.04 |
| 1,2,4-Triazole (weight %) | 0.10 |
| Glycine (weight %) | 2.0 |
| Glycerol (weight %) | 1.0 |
| Potassium hydroxide (ppm) | 47 |
| Proxel ® GXL (weight %) | 0.02 |
| H₂O₂ (weight %) | 1.0 |
| Isopropanol (weight %) | 1.0 |
| TINUVIN 328 (weight %) | 0.01 |
| Water (weight %) | Balance |
| pH | 7.37 |
| Copper removal rate at 2.0 psi (Å/min) | 7359 |
| Copper removal rate at 1.0 psi (Å/min) | 3358 |
| Tantalum removal rate at 1.0 psi (Å/min) | 2 |
| Tantalum nitride removal rate at 1.0 psi (Å/min) | 6 |
| Black Diamond ® removal rate at 1.0 psi (Å/min) | 2 |
| PETEOS removal rate at 1.0 psi (Å/min) | 0 |

The present invention has been set forth with regard to one or more preferred embodiments, however, the scope of the present invention should be ascertained from the claims which follow.

What is claimed is:

1. A polishing composition comprising:
a) an abrasive; and
b) a compound having the structure: 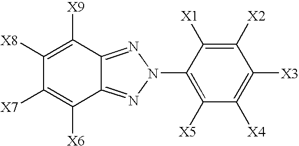
wherein at least one of X₁—-X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group.

2. The composition of claim 1 wherein the at least one of X₁—X₉ is —OH that is present at X₁.

3. The composition of claim 1 wherein the at least one branched C₄-C₁₄ alkyl group or branched C₄-C₁₄ aralkyl group is a branched C₄-C₁₀ alkyl group or a branched C₄-C₁₀ aralkyl group.

4. The composition of claim 3 wherein the at least one branched C₄-C₁₀ alkyl group or branched C₄-C₁₀ aralkyl group is a branched C₄-C₈ alkyl group or a branched C₄-C₈ aralkyl group.

5. The composition of claim 1 wherein at least two of X₁—X₉ are branched C₄-C₁₄ alkyl groups or branched C₄-C₁₄ aralkyl groups.

6. The composition of claim 2 wherein the at least one branched C₄-C₁₄ alkyl group or branched C₄-C₁₄ aralkyl group is present at X₂that is located ortho to the —OH that is present at X₁.

7. The composition of claim 2 wherein the at least one branched C₄-C₁₄ alkyl group or branched C₄-C₁₄ aralkyl group is present at X₄that is located para to the —OH that is present at X₁.

8. The composition of claim 1 wherein the alkylene ester group has the structure:
—(CH₂)ₙCO₂Y
where n=1-6; Y is selected from the group consisting of a C₁-C₁₀ alkyl group and —[(CH₂)₂—O]ₙ—H

9. The composition of claim 1 wherein the pH is in the range from 6.0 to 8.5.

10. The composition of claim 1 wherein the compound is selected from the group consisting of:

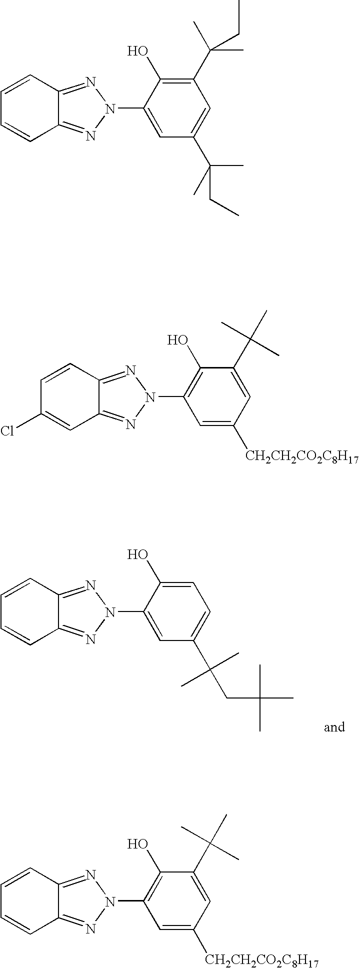

11. The composition of claim 1 wherein the compound is a mixture of 3 components having the structures:

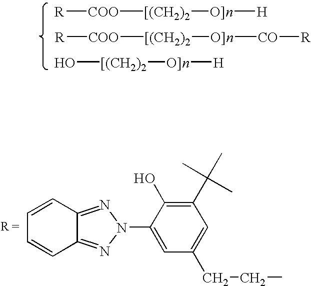

12. The composition of claim 1 further comprising an oxidizing agent.

13. The composition of claim 12 wherein the oxidizing agent is hydrogen peroxide.

14. The composition of claim 8 wherein Y is a C₆-C₈ alkyl group.

15. The composition of claim 1 further comprising a compound selected from the group consisting of isothiazolines and benzisothiazolines.

16. The composition of claim 1 wherein the compound is present at a level ranging from 0.001 weight % to 0.1 weight %.

17. The composition of claim 10 wherein the compound is selected from the group consisting of:

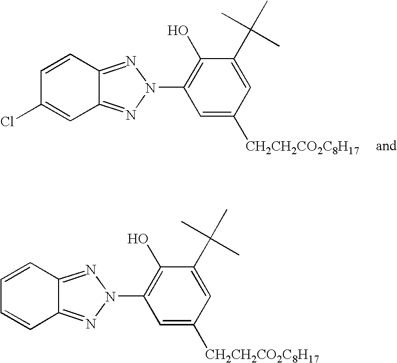

18. A polishing composition comprising:
a) an abrasive; and
b) a compound having the structure: 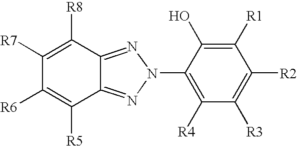
wherein at least one of R₁—R₈ is a branched C₄-C₁₄ alkyl group or a branched C₄-C₁₄ aralkyl group, and R₁—R₈ are independently selected from the group consisting of —H, —Cl, —F, —Br, —OH, —OR, a branched C₄-C₁₄ alkyl group, a branched C₄-C₁₄ aralkyl group, and a alkylene ester group, where R is a C₁-C₈ alkyl group.

19. A polishing composition comprising:
a) a compound having the structure: 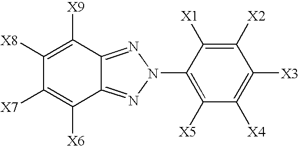
wherein at least one of X₁—X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group.

20. A polishing method comprising the steps of:
A) placing a substrate in contact with a polishing pad;
B) delivering a polishing composition comprising
a)an abrasive; and
b) a compound having the structure: 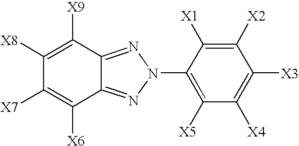
wherein at least one of X₁—X₉ is —OH, at least one of X₁—X₉ is a branched C₄-C₁₄ alkyl group or a branched C₄-C₁₄ aralkyl group, and X₁—X₉ are independently selected from the group consisting of —H, —Cl, —F, —Br, —OH, —OR, a C₁-C₁₄ alkyl group, a C₁-C₁₄ aralkyl group, and a alkylene ester group, where R is a C₁-C₈ alkyl group; and;
C) polishing the substrate with the polishing composition.

21. The method of claim 19 wherein the polishing method is a chemical mechanical planarization method for planarizing a substrate comprising copper, dielectric, and barrier layer.
